(19) United States
(12) Patent Application Publication
(10) Pub. No.: US 2011/0147751 A1
(43) Pub. Date: Jun. 23, 2011

(54) DISPLAY PANEL SUBSTRATE, DISPLAY PANEL, METHOD FOR MANUFACTURING DISPLAY PANEL SUBSTRATE, AND METHOD FOR MANUFACTURING DISPLAY PANEL

(75) Inventor: Hideaki Sunohara, Osaka-shi (JP)

(73) Assignee: SHARP KABUSHIKI KAISHA, Osaka-shi, Osaka (JP)

(21) Appl. No.: 13/000,156

(22) PCT Filed: Apr. 22, 2009
(86) PCT No.: PCT/JP2009/057954

§ 371 Date: Mar. 9, 2011

(30) Foreign Application Priority Data
Jun. 20, 2008 (JP) 2008-161539

(51) Int. Cl. H01L 33/08; H01L 33/62

(52) U.S. Cl. 257/59; 438/34; 257/E33.062

(57) ABSTRACT

A display panel substrate in which the width of a trace can be reduced without impairing a signal transfer capability of the trace. A display panel substrate (1) includes abase (12) that has a substantially semicircular cross-section in a direction perpendicular to a longitudinal direction of the base (12), and a trace (13) that has a thin film shape and has a longitudinal direction substantially parallel to the longitudinal direction of the base (12), at least a portion of the trace being superimposed on the base 12, at least a portion of the trace having a substantially arc cross-section in a direction perpendicular to the longitudinal direction of the base (12).

### TECHNICAL FIELD

The present invention relates to a display panel substrate, a display panel, a method for manufacturing a display panel substrate, and a method for manufacturing a display panel. The present invention specifically relates to a display panel substrate on which a trace that has a thin film shape and a thin line shape is provided, a display panel that includes the display panel substrate, a method for manufacturing a display panel substrate on which a trace that has a thin film shape and a thin line shape is formed, and a method for manufacturing a display panel.

### BACKGROUND ART

A generally used active matrix liquid crystal display panel includes a TFT array substrate and a common substrate (color filter). The substrates are disposed opposed to each other leaving a given small gap therebetween, and liquid crystals are filled and sealed between the substrates. A variety of given traces that have a thin film shape and a thin line shape such as a data line (source line), a scanning line (gate line), and a drain line are provided on one surface of the TFT array substrate (the surface that faces the common substrate).

In the field of the liquid crystal display panel, there is a demand for improving an aperture ratio. The “aperture ratio” refers to the percentage of the area of a light transmissive region in a display region (or in one pixel). The improvement of the aperture ratio can promote effective use of light emitted from a light source and improve brightness of the display panel. In order to improve the aperture ratio, it is necessary to lower the ratio of the area of a light shielding member in the display region (or in one pixel). Examples of the light shielding member include the data line, the signal line, and the drain line. Thus, in order to decrease the area of the light shielding member, reduction of the width of the trace may be performed.

However, the reduction of the width of the trace such as the data line, the scanning line, and the drain line could cause the following problem. Because of a recent trend toward a large area liquid crystal display device and high frequency signals to drive the liquid crystal display panel, there is a demand for improving a signal transfer capability of the trace. The reduction of the width of the trace decreases the cross-sectional area of the trace, which increases electrical resistance of the trace. As a result, the signal transfer capability of the trace could be impaired.

In order to improve the signal transfer capability of the trace (or in order to minimize or prevent the impairment of the signal transfer capability of the trace), the material of the trace may be changed to a material with lower electrical resistance, or the thickness of the trace may be increased. However, in the configuration that the material of the trace is changed to the material with lower electrical resistance, the process of film formation should be significantly changed in accordance with the change of the material. In the configuration that the thickness of the trace is increased, not only the material cost could be increased but also the film formation capability could be degraded.

In addition, in the field of the liquid crystal display panel, there is a demand for increasing a channel length of a TFT arranged to drive the pixel. The “channel length of the TFT” refers to a distance between a source electrode and a drain electrode of the TFT that are opposed to each other with a small space between them. The increase in the channel length of the TFT makes it possible to supply sufficient current to a pixel electrode in a short period of time. In order to increase the channel length of the TFT, it is generally necessary to increase the size of the TFT. However, the increase in the size of the TFT could lower the aperture ratio of the pixel.

In order to obtain an action and effect similar to the configuration that the channel length of the TFT is increased, the material of a semiconductor film in a channel region may be changed so as to improve the charge-transfer rate in the channel region. However, in the configuration that the material of the semiconductor film is changed, the process of film formation should be significantly changed in accordance with the change of the material.

### Patent Literature

PLT1: JP 2005-191113

PLT2: JP 2007-299972

### SUMMARY OF INVENTION

### Technical Problem

An object of the invention is to overcome the problems described above and to provide a display panel substrate in which the width of a trace can be reduced without impairing the signal transfer capability of the trace, a display panel, a method for manufacturing a display panel substrate, and a method for manufacturing a display panel. Another object of the invention is to provide a display panel substrate in which a signal transfer capability of a trace can be improved without increasing the width of the trace, a display panel, a method for manufacturing a display panel substrate, and a method for manufacturing a display panel. Yet another object of the present invention is to provide a display panel substrate in which an aperture ratio of a pixel can be improved while maintaining a signal transfer capability of a trace, a display panel, a method for manufacturing a display panel substrate, and a method for manufacturing a display panel. Yet another object of the present invention is to provide a display panel substrate in which a channel length of a TFT can be increased without increasing the size of the TFT or changing the material of a semiconductor film, a display panel, a method for manufacturing a display panel substrate, and a method for manufacturing a display panel.

### Solution to Problem

In order to overcome the problems described above, preferred embodiments of the present invention provide a display panel substrate that includes a base that has a substantially semicircular cross-section, and a trace that has a thin film shape, at least a portion of the trace being superimposed on the base.

Preferred embodiments of the present invention also provide a display panel substrate that includes a base that has a substantially semicircular cross-section in a direction perpendicular to a longitudinal direction of the base, and a trace that has a thin film shape and has a longitudinal direction substantially parallel to the longitudinal direction of the base, at least a portion of the trace being superimposed on the base, at least a portion of the trace having a substantially arc cross-section in a direction perpendicular to the longitudinal direction of the trace.

The display panel substrate described above preferably includes a pixel electrode, and a thin film transistor arranged to drive the pixel electrode, and the trace preferably includes at least one of a data line arranged to transfer an image signal to the thin film transistor, a scanning line arranged to transfer a selection pulse to a gate electrode of the thin film transistor, and a drain line arranged to electrically connect a drain electrode of the thin film transistor and the pixel electrode.

Preferred embodiments of the present invention also provide a display panel substrate that includes a pixel electrode, a thin film transistor that is arranged to drive the pixel electrode and includes a drain electrode and a channel region, and a base that has a substantially semicircular cross-section, wherein at least portions of the drain electrode and the channel region are superimposed on the base.

The base is preferably made from a photosensitive resin material.

Preferred embodiments of the present invention also provide a display panel that includes the display panel substrate described above and a common substrate.

Preferred embodiments of the present invention also provide a method for manufacturing a display panel substrate that includes the steps of forming a base that has a substantially square cross-section, making the base take a substantially semicircular cross-section, and forming a trace at least a portion of which is superimposed on the base.

Preferred embodiments of the present invention also provide a method for manufacturing a display panel substrate that includes the steps of forming a base that has a thin film shape and has a substantially square cross-section in a direction perpendicular to a longitudinal direction of the base, making the base take a substantially semicircular cross-section in a direction perpendicular to the longitudinal direction of the base, and forming a trace that has an area that has a longitudinal direction substantially parallel to the longitudinal direction of the base, at least a portion of the area being superimposed on the base, at least a portion of the area having a substantially arc cross-section in a direction perpendicular to the longitudinal direction of the trace.

Preferred embodiments of the present invention also provide a method for manufacturing a display panel substrate that includes the steps of forming a base that has a thin film shape on a transparent substrate, making the base take a substantially semicircular cross-section in a direction perpendicular to a longitudinal direction of the base, and forming a scan line that has an area that has a longitudinal direction substantially parallel to the longitudinal direction of the base, a portion of the area being superimposed on the base.

Preferred embodiments of the present invention also provide a method for manufacturing a display panel substrate that includes the steps of forming a base that has a thin film shape on a transparent substrate subjected to a given process, making the base take a substantially semicircular cross-section in a direction perpendicular to a longitudinal direction of the base, and forming a data line that has an area that has a longitudinal direction substantially parallel to the longitudinal direction of the base, at least a portion of the area being superimposed on the base.

Preferred embodiments of the present invention also provide a method for manufacturing a display panel substrate that includes the steps of forming a base that has a thin film shape on a transparent substrate subjected to a given process, making the base take a substantially semicircular cross-section in a direction perpendicular to the longitudinal direction of the base, and forming a drain line that has an area that has a longitudinal direction substantially parallel to the longitudinal direction of the base, at least a portion of the area being superimposed on the base.

Preferred embodiments of the present invention also provide a method for manufacturing a display panel substrate on which a thin film transistor including a gate electrode, a source electrode, and a drain electrode is formed, and the method includes the steps of forming a base that has a thin film shape and is superimposed on the gate electrode, making the base take a substantially semicircular cross-section in a direction perpendicular to a longitudinal direction of the base, and forming the drain electrode at least a portion of which is superimposed on the base.

The base is preferably made from a photosensitive resin material.

It is preferable that the step of making the base take a substantially semicircular cross-section in the direction perpendicular to the longitudinal direction of the base includes the step of subjecting the base to heating or curing.

Preferred embodiments of the present invention provide a method for manufacturing a display panel that includes one of the above-described methods for manufacturing the display panel substrate.

### Advantageous Effects of Invention

According to the preferred embodiments of the present invention in which the trace is superimposed on the base that has the substantially semicircular cross-section, the signal transfer capability of the trace can be improved by increasing the cross-sectional area of the trace without increasing the apparent width of the trace. In other words, the width of the trace can be reduced without impairing the signal transfer capability of the trace. Because the reduction of the width of the trace improves an aperture ratio of a pixel, the improvement of the aperture ratio of the pixel can be achieved while maintaining the signal transfer capability of the trace.

With the configuration that the channel region and the drain electrode of the thin film transistor are superimposed on the base that has the substantially semicircular cross-section, a channel length of the TFT can be increased without increasing the apparent size of the TFT. The increase in the channel length of the TFT makes it possible to supply sufficient current to a pixel electrode in a short period of time, which improves the capability of the TFT. As a result, the capability of the TFT can be improved by increasing the channel length of the TFT without increasing the size of the TFT and lowering the aperture ratio.

In addition, the apparent size of the TFT can be decreased while maintaining the substantial channel length of the TFT. Thus, the aperture ratio can be improved by decreasing the size of the TFT while maintaining the capability of the TFT.

With the configuration that the photosensitive resin material is used for the base, the base can be easily formed by photolithography. In addition, with the configuration that the resin material is used for the base, the resin is softened by heating or curing, and the resin material takes a substantially semicircular cross-section by surface tension of the softened resin. Accordingly, the base that has the substantially semicircular cross-section can be formed by an easy process.

### BRIEF DESCRIPTION OF DRAWINGS

FIG. 1 is an external perspective view schematically showing the structure of a trace that is provided on a display panel substrate according to a preferred embodiment of the present invention.

FIGS. 2A and 2B are cross-sectional views (along a direction perpendicular to a longitudinal direction of the trace) that provide a comparison between a configuration that the trace is provided on a base and a configuration that the base is not included.

FIGS. 3A to 3D are cross-sectional views schematically showing the method for forming the base and the trace in a stepwise manner.

FIGS. 4A to 4E are cross-sectional views schematically showing a method for forming the base and the trace in a stepwise manner.

FIG. 5 is an external perspective view schematically showing the structure of the display panel substrate according to the preferred embodiment of the present invention.

FIG. 6 is a plan view schematically showing a pixel electrode of one pixel and one TFT from among a plurality of pixel electrodes and a plurality of TFTs that are arranged on the display panel substrate according to the preferred embodiment of the present invention.

FIG. 7 is a cross-sectional view schematically showing the cross-sectional structure of the display panel substrate according to the preferred embodiment of the present invention along the line A-A shown in FIG. 6.

FIG. 8 is a cross-sectional view along the line B-B shown in FIG. 6.

FIG. 9 is a cross-sectional view along the line C-C shown in FIG. 6.

FIG. 10 is a cross-sectional view schematically showing the cross-sectional structure of a channel region and a drain electrode of the TFT along the line D-D shown in FIG. 6.

FIGS. 11A to 11C are cross-sectional views schematically showing the steps of a method for forming the display panel substrate according to the preferred embodiment of the present invention.

FIGS. 12A to 12C are cross-sectional views schematically showing the steps of the method for forming the display panel substrate according to the preferred embodiment of the present invention.

FIGS. 13A to 13C are cross-sectional views schematically showing the steps of the method for forming the display panel substrate according to the preferred embodiment of the present invention.

FIGS. 14A to 14C are cross-sectional views schematically showing the steps of the method for forming the display panel substrate according to the preferred embodiment of the present invention.

FIGS. 15A to 15C are cross-sectional views schematically showing the steps of the method for forming the display panel substrate according to the preferred embodiment of the present invention.

FIGS. 16A to 16C are cross-sectional views schematically showing the steps of the method for forming the display panel substrate according to the preferred embodiment of the present invention.

FIGS. 17A to 17C are cross-sectional views schematically showing the steps of the method for forming the display panel substrate according to the preferred embodiment of the present invention.

FIGS. 18A to 18C are cross-sectional views schematically showing the steps of the method for forming the display panel substrate according to the preferred embodiment of the present invention.

FIGS. 19A to 19C are cross-sectional views schematically showing the steps of the method for forming the display panel substrate according to the preferred embodiment of the present invention.

FIG. 20 is an external perspective view schematically showing the structure of a display panel that uses the display panel substrate according to the preferred embodiment of the present invention.

FIGS. 21A to 21C are views schematically showing the structure of a common substrate (color filter). FIG. 21A is a perspective view schematically showing the overall structure of the common substrate (color filter), FIG. 21B is a plan view showing the structure of one pixel that is provided on the common substrate (color filter), and FIG. 21C is a cross-sectional view showing the cross-sectional structure of the pixel along the F-F line in FIG. 21B.

### DESCRIPTION OF EMBODIMENTS

A detailed description of preferred embodiments of the present invention will now be provided with reference to the accompanying drawings. A display panel substrate 1 according to the preferred embodiment of the present invention is a TFT array substrate for a liquid crystal display panel.

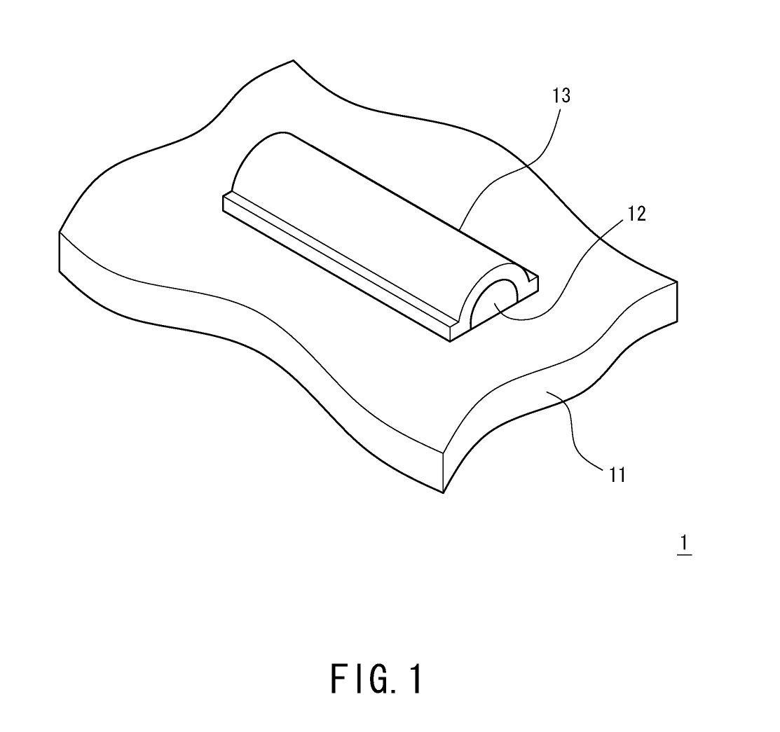

FIG. 1 is an external perspective view schematically showing the structure of a given trace 13 that is provided to the display panel substrate 1 according to the preferred embodiment of the present invention. As shown in FIG. 1, the display panel substrate 1 according to the preferred embodiment of the present invention has such a structure that a base 12, and the given trace 13 that is superimposed on the base 12 are provided on a transparent substrate 11.

As shown in FIG. 1, the base 12 is provided on the transparent substrate 11. The base 12 has a shape substantially same as the shape of the trace 13, and has a substantially semicircular cross-section in a direction perpendicular to a longitudinal direction of the base 12. The base 12 is preferably made from a thermoplastic resin material. The given trace 13 is superimposed on the base 12. In other words, the trace 13 is laminated on the base 12. The trace 13 has a thin film shape and a thin line shape. Thus, the trace 13 includes a portion that has a substantially arc cross-section in a direction perpendicular to a longitudinal direction of the trace 13.

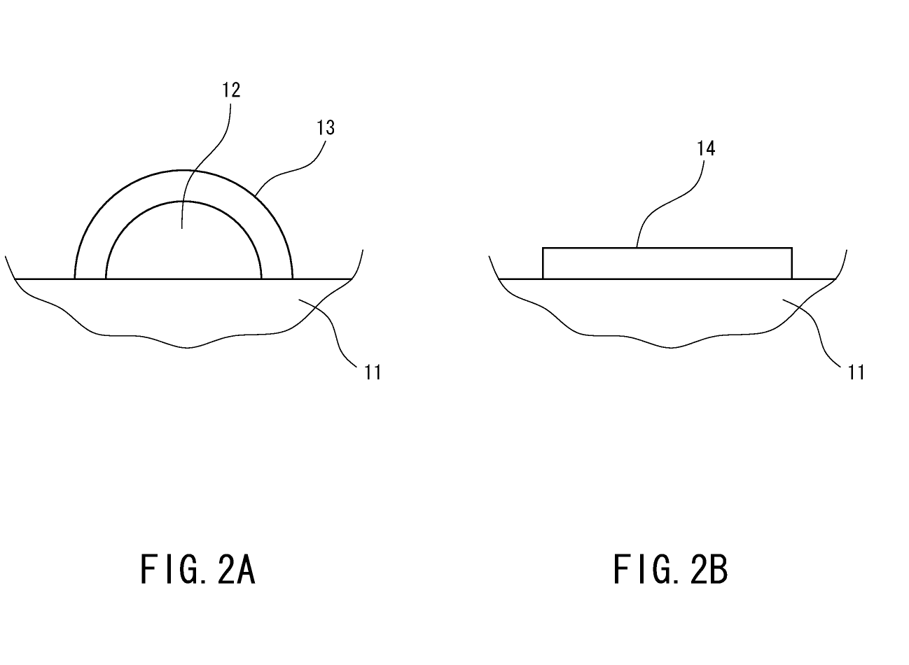

With this configuration, the width of the trace 13 can be reduced while maintaining a signal transfer capability of the trace 13 as compared to a configuration that the base 12 is not included. FIGS. 2A and 2B are cross-sectional views (along a direction perpendicular to the longitudinal direction of the trace 13 or a longitudinal direction of a trace 14) that provide a comparison between the configuration that the trace 13 is provided on the base 12 and the configuration that the base 12 is not included. Provided that the cross-sectional area of the trace 13 in FIG. 2A and the cross-sectional area of the trace 14 in FIG. 2B are equal, the width of the trace 13 in the configuration that the trace 13 is provided on the base 12 that has the substantially semicircular cross-section can be smaller than the width of the trace 14 in the configuration that the base 12 is not included.

To be specific, when the radius of the semicircle in the base 12 is 5.0 μm and the thickness of the trace 13 is 0.3 μm, then the width of the trace 13 is 5.6 μm, and the cross-sectional area of the trace 13 is about 2.5 μm². In the configuration that the base 12 is not included and the trace 14 is provided as shown in FIG. 2B (i.e., the trace 14 has a substantially square cross-section), when the thickness of the trace 14 is 0.3 μm, then the width of the trace 14 should be about 8.3 μm in order to make the cross-sectional area of the trace 14 be 2.5 μm² that is the same value as the cross-sectional area of the trace 13 in the configuration that the trace 13 is provided on the base 12.

Thus, the configuration that the trace 13 is provided on the base 12 can achieve reduction of the width of the trace 13 by ((8.3−5.6)/8.3)×100=32.5(%) as compared to the configuration that the base 12 is not included. Therefore, the width of the trace 13 can be reduced while maintaining the signal transfer capability of the trace 13. As a result, an aperture ratio in the liquid crystal display panel can be improved.

Comparing the configuration that the base 12 that has the substantially semicircular cross-section is included and the configuration that the base 12 is not included, if the width of the trace 13 and the width of the trace 14 are equal, the cross-sectional area of the trace 13 in the configuration that the base 12 that has the substantially semicircular cross-section is provided is larger. Accordingly, the signal transfer capability of the trace 13 can be improved without increasing the width of the trace 13.

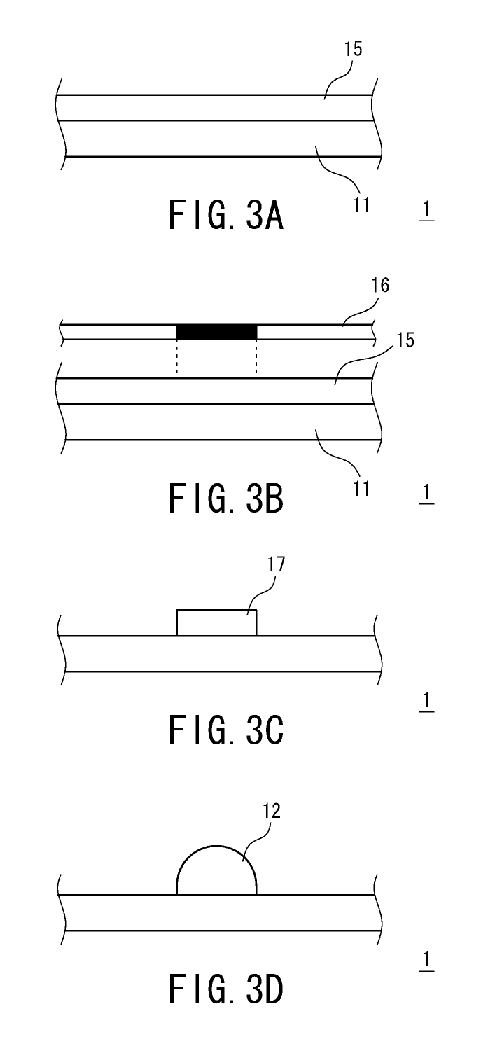

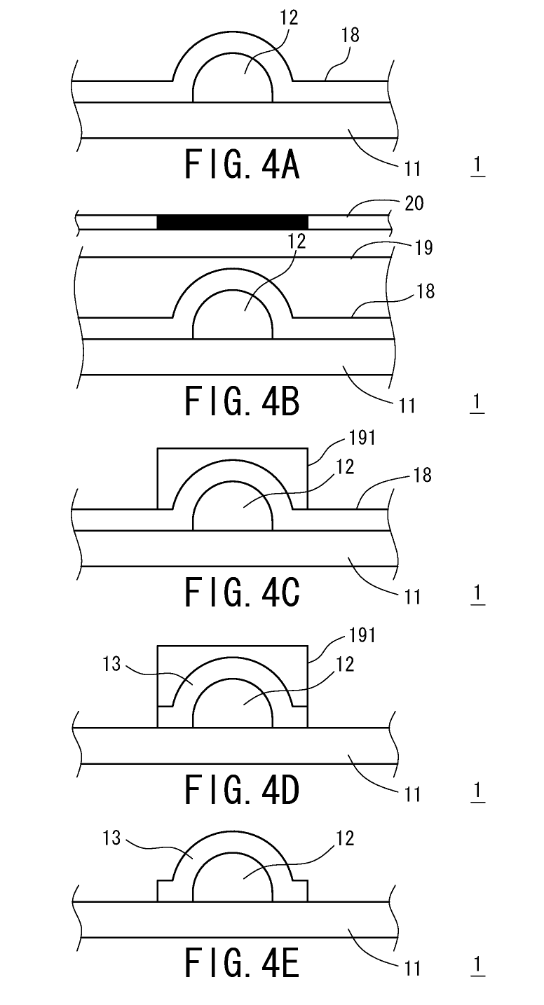

Next, a description of a method for forming the base 12 and the trace 13 is provided. FIGS. 3A to 3D and FIGS. 4A to 4E are cross-sectional views schematically showing the method for forming the base 12 and the trace 13 in a stepwise manner. FIGS. 3A to 4E show cross-sections on a plane perpendicular to the longitudinal directions of the base 12 and the trace 13.

First, a layer 15 of a photosensitive resin material that is a material of the base 12 is formed on the transparent substrate 11 as shown in FIG. 3A. The photosensitive resin material maybe positive or negative, and a positive photosensitive resin material is used as an example herein. A method for forming the photosensitive resin material layer 15 includes a method for coating the transparent substrate 11 with the photosensitive resin material preferably with the use of a spin coater.

For the photosensitive resin material, a photosensitive acrylic resin is preferably used. Table. 1 shows the composition of the photosensitive resin material and structural formulae of materials of the photosensitive resin material. To be specific, a solution that contains 20-30% acrylic resin as a base resin, 1-10% naphthoquinone diazide sulfonic ester as a photosensitizing agent, and 65-75% diethylene glycol methylethyl ether as a solvent is preferably used.

TABLE 1

| Kind | Name | Content (%) | Structural formula |
|---|---|---|---|
| Base resin | Acrylic resin | 20-30 | 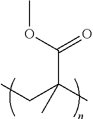 |
| Photo- sensitizing agent | Naphthoquinone diazide sulfonic ester | 1-10 | 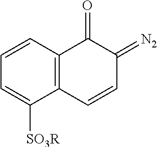 |
| Solvent | Diethylene glycol methylethyl ether | 65-75 | |

The formed photosensitive resin material layer 15 is subjected to exposure with the use of a photomask 16 as shown in FIG. 3B. To be specific, a portion that becomes the base 12 is shielded by the photomask 16, and the other port ions are irradiated with light energy. Then, the photosensitive resin material layer 15 subjected to the exposure is subjected to developing. After the developing, the shielded portion 17 is left on the transparent substrate 11, and the other portions (the portions irradiated with light energy) are removed as shown in FIG. 3C.

Then, heating (or curing) is performed on the photosensitive resin material 17 that is left on the transparent substrate 11 by the developing. In the early stage of the heating (curing), the photosensitive resin material is softened, and the cross-section of the photosensitive resin material changes from a square cross-section to a substantially semicircular cross-section. In the later stage of the heating (curing), the photosensitive resin material is hardened having the substantially semicircular cross-section. As a result, the base 12 that has the substantially semicircular cross-section is obtained as shown in FIG. 3D.

Then, a metal thin film 18 that is a material of the trace 13 is formed on the transparent substrate 11 subjected to the above process on which the base 12 is formed as shown in FIG. 4A. For a method for forming the metal thin film 18, sputtering is preferably used.

Then, a layer 19 of a photoresist material is formed on the metal thin film 18, and the formed photoresist material layer 19 is subjected to exposure with the use of a given photomask 20 as shown in FIG. 4B. For the photoresist material, a photosensitive resin material is preferably used. For a method for forming the photoresist material layer 19, a method for applying the photoresist material with the use of a spin coater is preferably used. In the exposure, if the photoresist material is positive, a portion of the photoresist material that covers a portion of the metal thin film 18 that becomes the trace 13 (a portion superimposed on the base 12) is shielded, and portions of the photoresist material that cover the other portions of the metal thin film 18 are irradiated with light energy.

The photoresist material subjected to the exposure is subjected to developing, so that the shielded portion 191 is left on the metal thin film 18, and the other portions (the portions irradiated with light energy) are removed as shown in FIG. 4C. In other words, the portion of the metal thin film 18 that is superimposed on the base 12 is covered with the photoresist material, and the other portions of the metal thin film 18 are exposed.

Then, the exposed portions of the metal thin film 18 are removed by using the photoresist material 191 that is left on the metal thin film 18 as a mask. For a method for removing the exposed portions of the metal thin film 18, etching such as dry etching and wet etching may be used. Thus, the removal of the metal thin film 18 from the transparent substrate 11 is performed such that the portion covered with the photoresist material 191 is left on the transparent substrate 11.

Then, the photoresist material 191 is removed as shown in FIG. 4E. As a result, the structure that the trace 13 is superimposed on the base 12 that has the substantially semicircular cross-section is obtained.

Next, a description of the display panel substrate 1 that has the trace structure described above is provided.

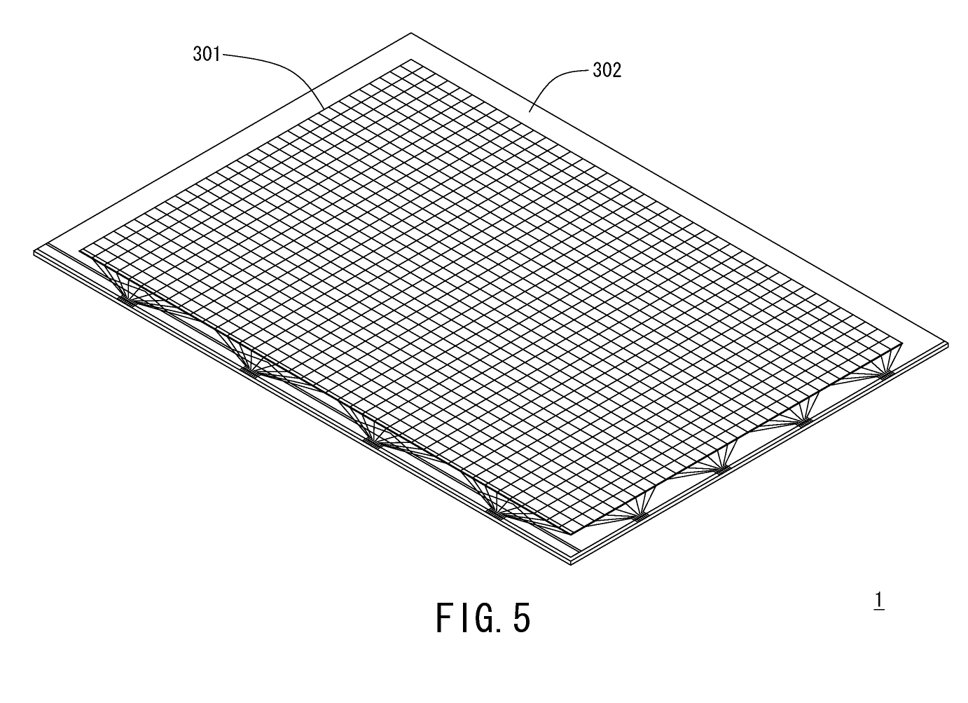

FIG. 5 is an external perspective view schematically showing the structure of the display panel substrate 1 according to the preferred embodiment of the present invention. As shown in FIG. 5, the display panel substrate 1 according to the preferred embodiment of the present invention includes a display region (active area) 301 and a panel frame region 302. In the display region (active area) 301, a plurality of pixel electrodes 32 are arranged in a matrix, and TFTs 31 arranged to drive the pixel electrodes 32 are provided. In the panel frame region 302, given lines arranged to transfer given signals to the TFTs 31 are provided.

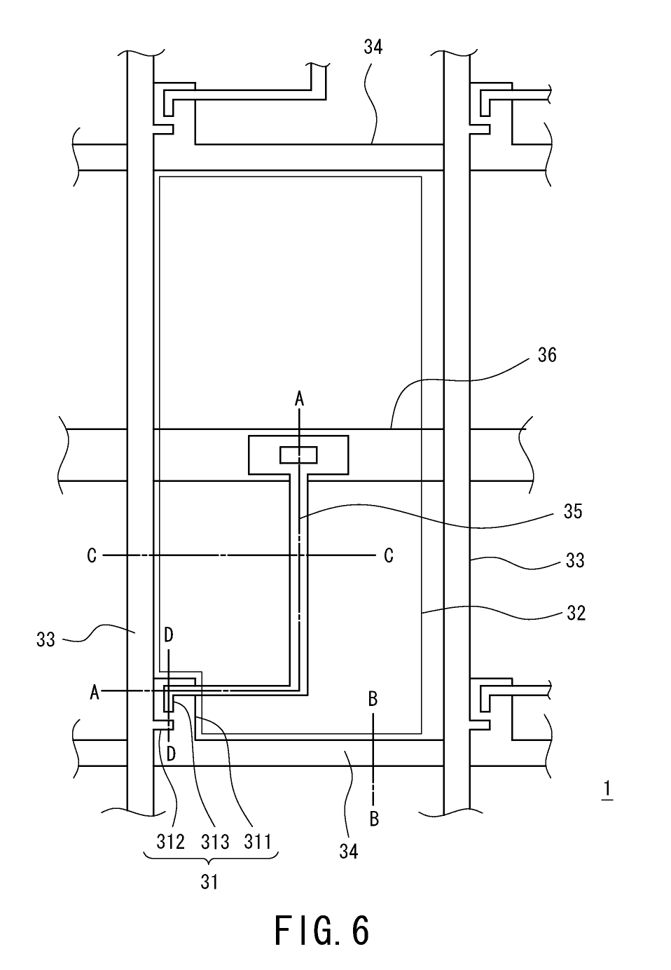

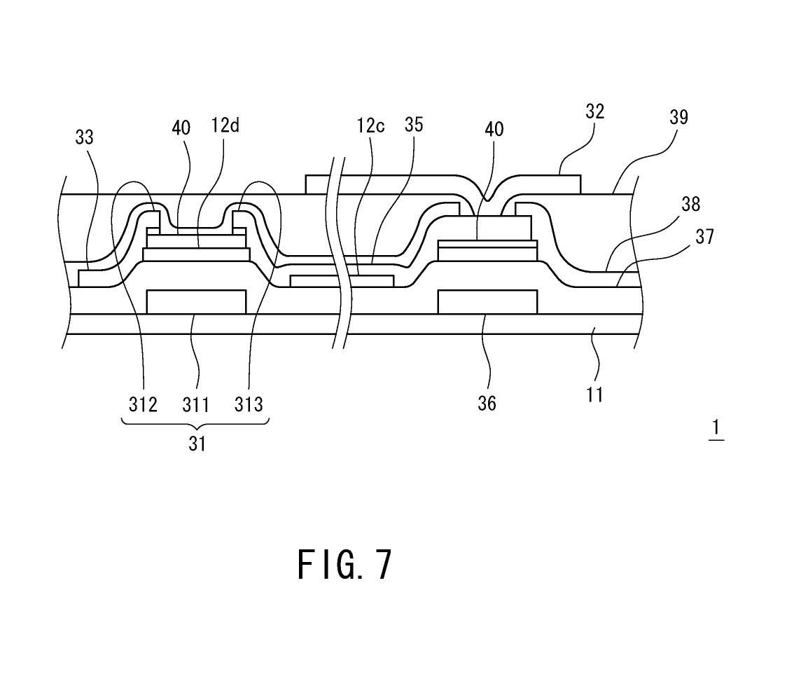

FIG. 6 is a plan view schematically showing a pixel electrode 32 of one pixel and one TFT 31 from among the plurality of pixel electrodes 32 and the plurality of TFTs 31 that are arranged on the display panel substrate 1 according to the preferred embodiment of the present invention. FIG. 7 is a cross-sectional view schematically showing the cross-sectional structure of the display panel substrate 1 according to the preferred embodiment of the present invention along the line A-A shown in FIG. 6.

As shown in FIGS. 6 and 7, the display panel substrate 1 according to the preferred embodiment of the present invention includes the transparent substrate 11, datelines (source lines) 33, scanning lines (gate lines) 34, drain lines 35, auxiliary capacitance signal lines 36, the TFTs 31, a gate insulator film (first insulator film) 37, a passivation film (second insulator film) 38, an organic insulator film (third insulator film) 39, and the pixel electrodes 32. The TFTs 31 each include gate electrodes 311, source electrodes 312, and drain electrodes 313.

The drain lines 35 refer to lines arranged to electrically connect the drain electrodes 313 of the TFTs 31 and the pixel electrodes 32. To be specific, one ends of the drain lines 35 are electrically continuous to the drain electrodes 313 of the TFTs 31. The other ends of the drain lines 35 are electrically continuous to the pixel electrodes 32. With this configuration, the drain lines 35 can transfer electrical signals outputted from the drain electrodes 313 of the TFTs 31 to the pixel electrodes 32.

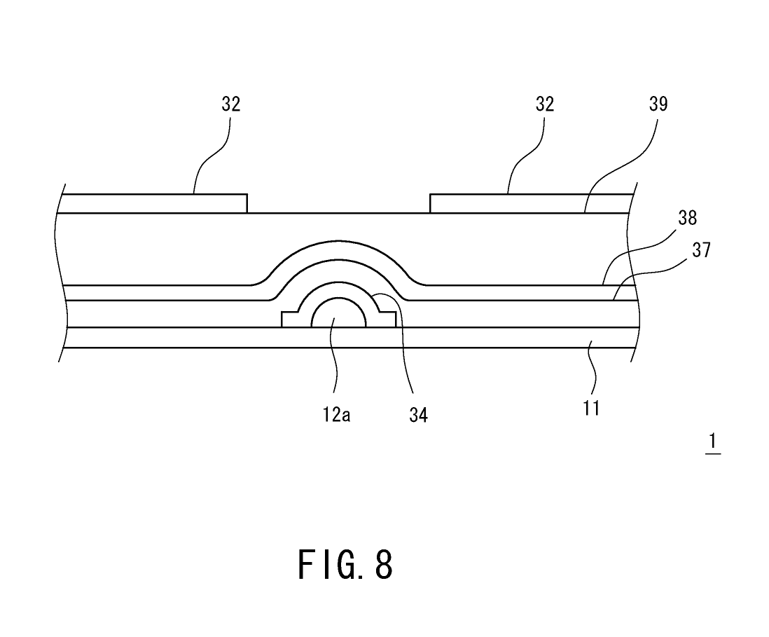

FIG. 8 is a cross-sectional view along the line B-B shown in FIG. 6. As shown in FIG. 8, a first base 12a that has a substantially semicircular cross-section is provided on the transparent substrate 11, and the scanning line 34 is superimposed on the first base 12a. With this configuration, the width of the scanning line 34 can be reduced while maintaining a signal transfer capability of the scanning line 34. Thus, the aperture ratio of the pixel can be improved. With this configuration, the cross-sectional area of the scanning line 34 can be increased without increasing the apparent width of the scanning line 34. As a result, the signal transfer capability of the scanning line 34 can be improved.

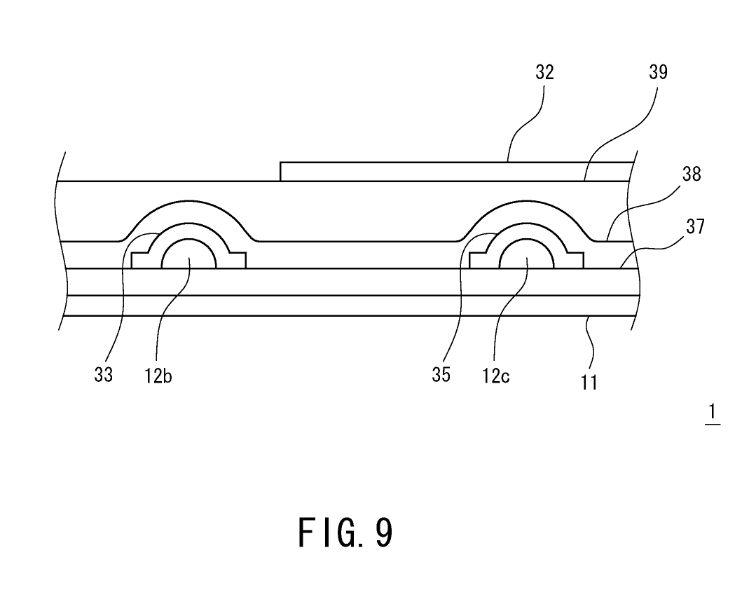

FIG. 9 is a cross-sectional view along the line C-C shown in FIG. 6. As shown in FIG. 9, a second base 12b that has a substantially semicircular cross-section and a third base 12c that has a substantially semicircular cross-section are provided on the gate insulator film (first insulator film) 37, and the data line 33 and the drain line 35 are superimposed on the bases 12b and 12c, respectively. With this configuration, the widths of the data line 33 and the drain line 35 can be reduced while maintaining signal transfer capabilities of the data line 33 and the drain line 35. Thus, the aperture ratio of the pixel can be improved. In addition, with this configuration, the cross-sectional areas of the data line 33 and the drain line 35 can be increased without increasing the apparent widths of the data line 33 and the drain line 35. Accordingly, the signal transfer capabilities of the data line 33 and the drain line 35 can be improved without lowering the aperture ratio.

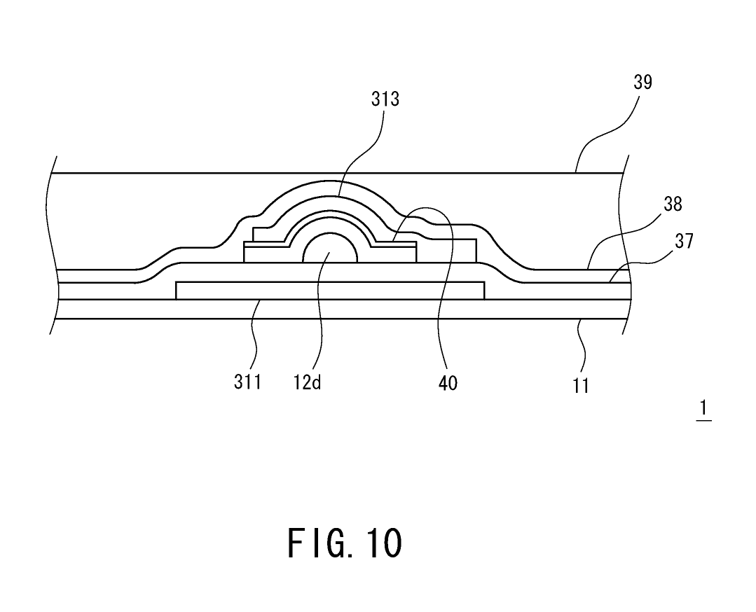

FIG. 10 is a cross-sectional view schematically showing the cross-sectional structure of the channel region and the drain electrode 313 of the TFT 31 along the line D-D shown in FIG. 6. As shown in FIG. 10, a fourth base 12d is provided on the first insulator film 37, and the semiconductor film 40 and the drain electrode 313 are superimposed on the fourth base 12d. A longitudinal direction of the fourth base 12d is substantially perpendicular to a longitudinal direction of the channel region of the TFT 31. With this configuration, the semiconductor film 40 and the drain electrode 313 within the channel region of the TFT 31 have an arch shape. Accordingly, the length of the drain electrode 313 that is opposed to the source electrode 312 of the TFT 31 can be made longer as compared to the configuration that the fourth base 12d is not included.

With this configuration, the channel length of the TFT 31 can be increased without increasing the apparent length of the drain electrode 313 of the TFT 31 or increasing the size of the TFT 31. The increase in the channel length of the TFT 31 makes it possible to supply sufficient current to the pixel electrode in a short period of time, which improves the capability of the TFT 31. As described above, the channel length of the TFT 31 can be increased without lowering the aperture ratio by increasing the size of the TFT 31.

Next, a method for manufacturing the display panel substrate 1 according to the preferred embodiment of the present invention is provided.

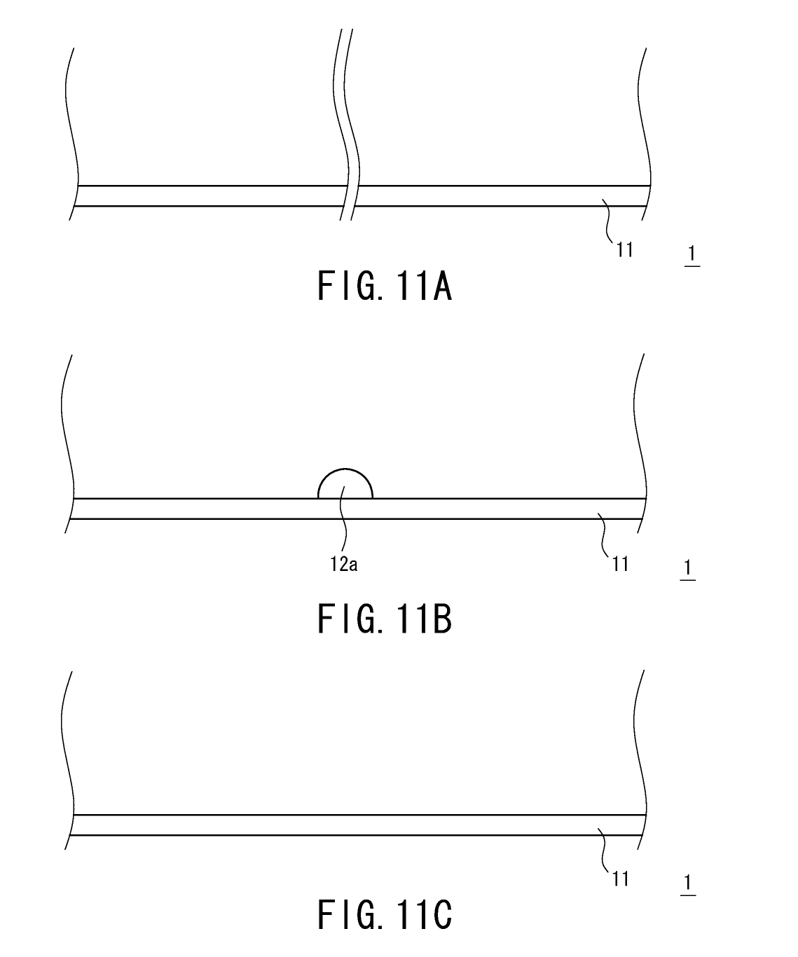

FIGS. 11A to 11C, FIGS. 12A to 12C, FIGS. 13A to 13C, FIGS. 14A to 14C, FIGS. 15A to 15C, FIGS. 16A to 16C, FIGS. 17A to 17C, FIGS. 18A to 18C, and FIGS. 19A to 19C are cross-sectional views schematically showing the steps of the method for forming the display panel substrate 1 according to the preferred embodiment of the present invention. Among FIGS. 11A to 19C, the drawings assigned A are cross-sectional views along the line A-A shown in FIG. 6, the drawings assigned B are cross-sectional views along the line B-B shown in FIG. 6, and the drawings assigned C are cross-sectional views along the line C-C shown in FIG. 6. In addition, the drawings assigned A to C of the same drawing number show cross-sections along the lines A-A, B-B, and C-C in the same step.

As shown in FIGS. 11A to 11C, the base of the scanning line (the first base 12a) is formed on the transparent substrate 11 (see FIG. 11B, not formed in areas shown in FIGS. 11A and 11B). The method for forming the first base 12a is as described above.

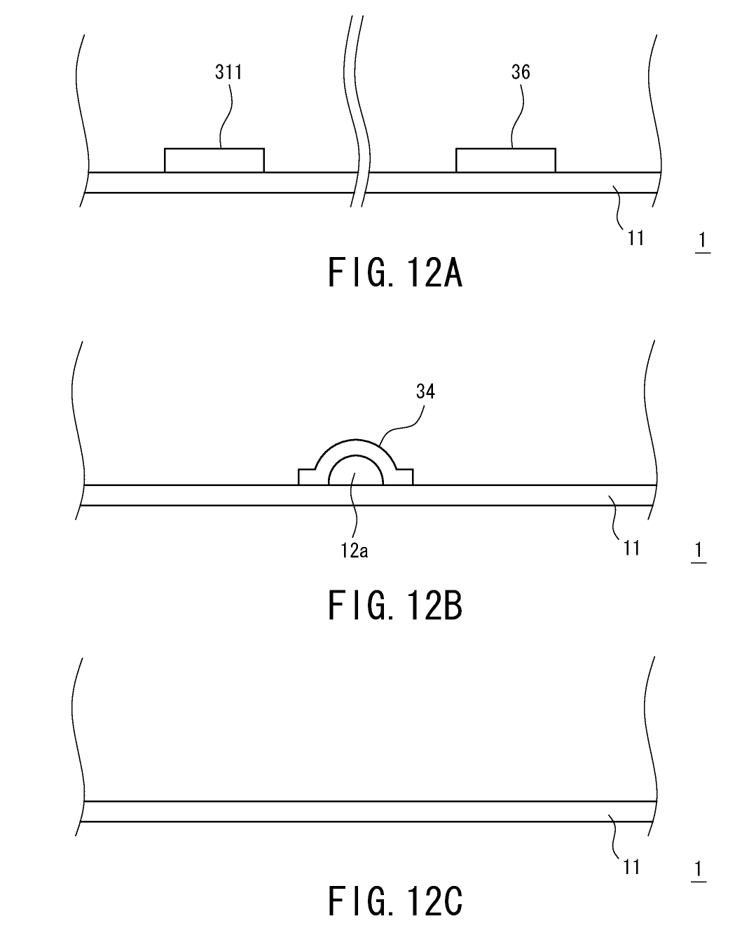

Then, as shown in FIGS. 12A and 12B, the scanning line 34, the auxiliary capacitance signal line 36, and the gate electrode 311 of the TFT 31 are formed in the display region (active area) 301 of the transparent substrate 11 (not formed in an area shown in FIG. 12C). As shown in FIG. 12B, the scanning line 34 is formed so as to be superimposed on the first base 12a formed in the above process.

To be specific, a single or multi-layer conductor film preferably made from titanium, chromium, tungsten, molybdenum, or aluminum (a first conductor film) is formed on the transparent substrate 11. For a method for forming the first conductor film, sputtering is preferably used. The thickness of the first conductor film is not specifically limited, and may be about 300 nm.

The formed first conductor film is subjected to patterning into the scanning line 34, the auxiliary capacitance signal line 36, and the gate electrode 311 of the TFT 31. For the patterning of the first conductor film, wet etching may be used. If the first conductor film is made from chromium, wet etching using a (NH₄)₂[Ce(NH₃)₆]+HNO₃+H₂O solution is preferably used.

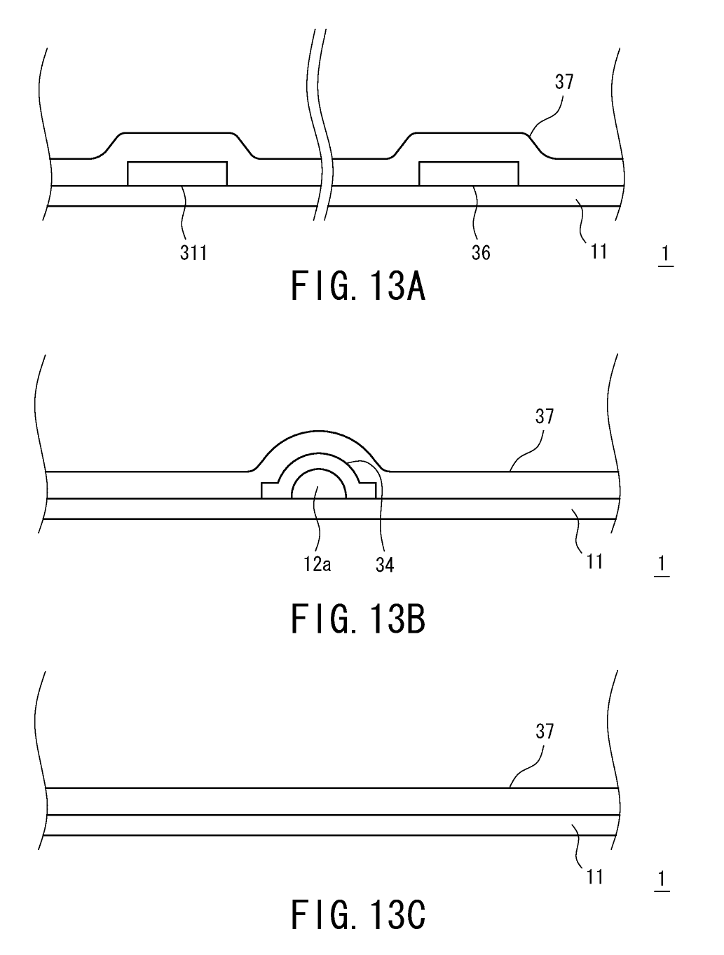

Then, as shown in FIGS. 13A to 13C, the gate insulator film (first insulator film) 37 is formed on the transparent substrate 11 subjected to the above processes. For the gate insulator film (first insulator film) 37, an SiNx film that has a thickness of about 300 nm is preferably used. For a method for forming the gate insulator film (first insulator film) 37, CVD may be used. When the gate insulator film (first insulator film) 37 is formed, the scanning line 34, the auxiliary capacitance signal line 36, and the gate electrode 311 of the TFT 31 are covered with the gate insulator film (first insulator film) 37 as shown in FIGS. 13A and 13B.

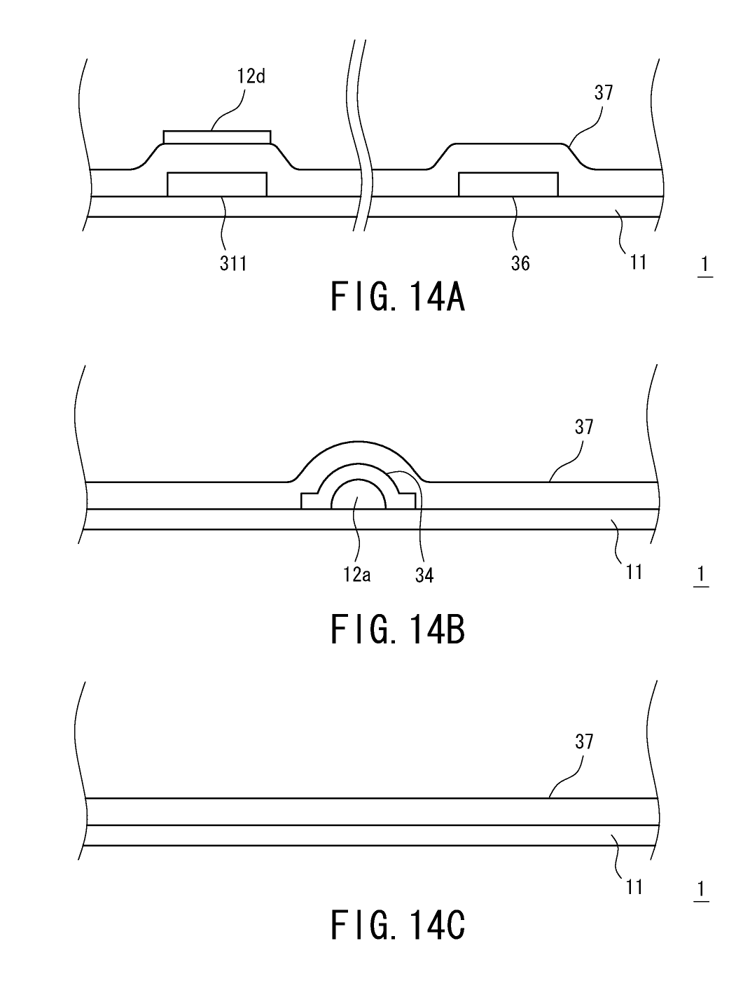

Then, the fourth base 12d is formed in an area where the channel region and the drain electrode 313 of the TFT 31 are to be formed. The fourth base 12d is not formed in areas shown in FIGS. 14B and 14C. The method for forming the fourth base 12d is as described above. The fourth base 12d extends in a direction perpendicular to the longitudinal direction of the channel region of the TFT 31. In other words, the longitudinal direction of the fourth base 12d and the longitudinal direction of the channel region of the TFT 31 intersect at right angles.

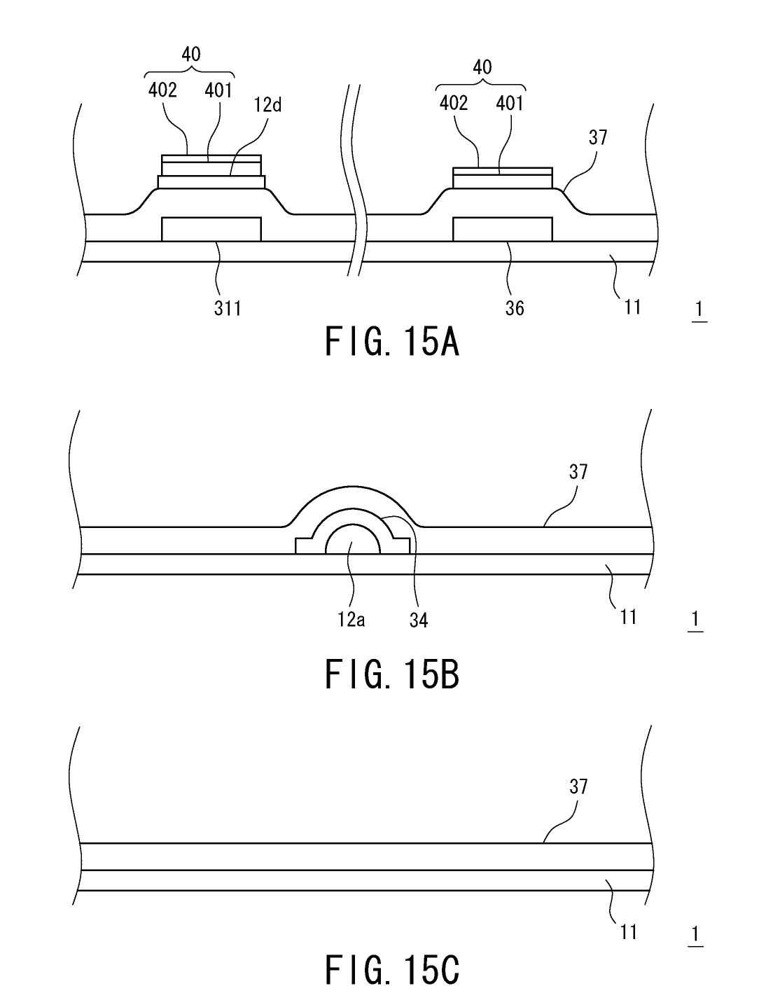

Then, as shown in FIG. 15A, the semiconductor film 40 that has a given shape is formed in given areas on the gate insulator film (first insulator film) 37. The semiconductor film 40 is not formed in areas shown in FIGS. 15B and 15C. To be specific, the semiconductor film 40 is formed in the area that is superimposed on the gate electrode 311 via the gate insulator film (first insulator film) 37 and the fourth base 12d and in the area that is superimposed on the auxiliary capacitance signal line 36 via the gate insulator film (first insulator film) 37. The semiconductor film 40 has a two-layer structure consisting of a first sub semiconductor film 401 and a second sub semiconductor film 402. For the first sub semiconductor film 401, an amorphous silicon film that has a thickness of about 100 nm is preferably used. For the second sub semiconductor film 402, an n⁺ amorphous silicon film that has a thickness of about 20 nm is preferably used.

For a method for forming the semiconductor film 40 (the first sub semiconductor film 401 and the second sub semiconductor film 402), CVD and photolithography are preferably used. To be specific, first, the materials of the semiconductor film 40 (the first sub semiconductor film 401 and the second sub semiconductor film 402) are deposited on the transparent substrate 11 subjected to the above processes by CVD. Then, the formed semiconductor film 40 (the first sub semiconductor film 401 and the second sub semiconductor film 402) is subjected to patterning into a given shape by photolithography. For the patterning, wet etching using an HF+HNO₃ solution or dry etching using a Cl₂ gas and an SF₆ gas is preferably used. Accordingly, the semiconductor film 40 (the first sub semiconductor film 401 and the second sub semiconductor film 402) is formed so as to be superimposed on the gate electrode 311 and on the auxiliary capacitance signal line 36 via the gate insulator film (first insulator film) 37.

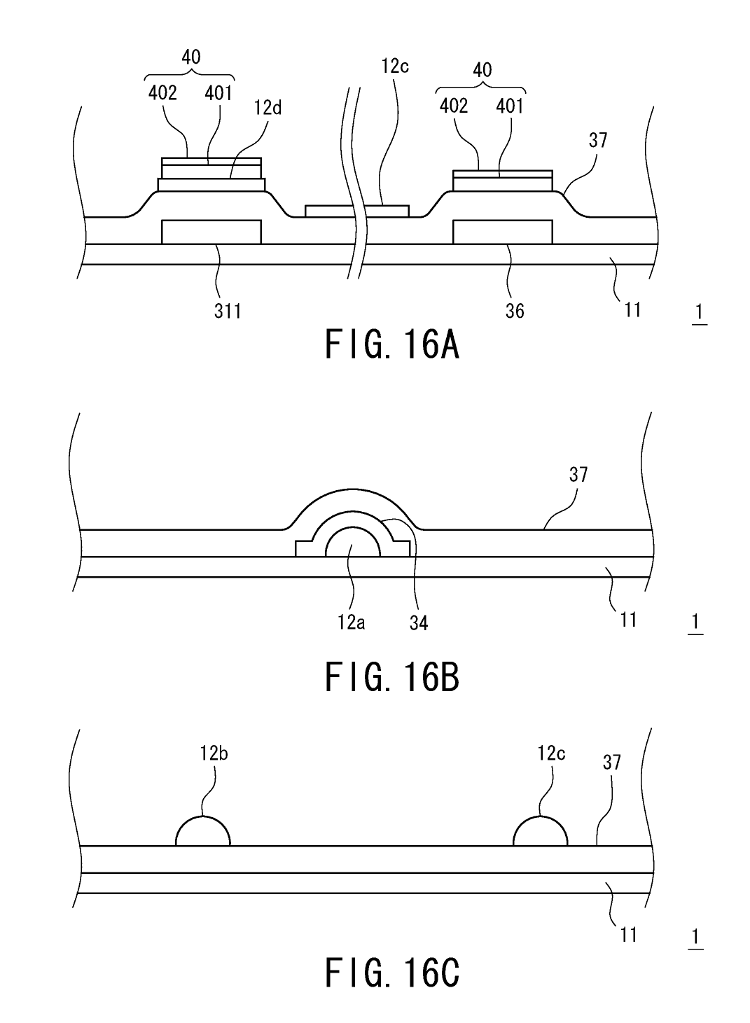

Then, the second base 12b and the third base 12c are simultaneously formed in the same process as shown in FIGS. 16A and 16C. In this process, the second base 12b and the third base 12c are not formed in an area shown in FIG. 16B. The method for forming the second base 12b and the third base 12 is as described above.

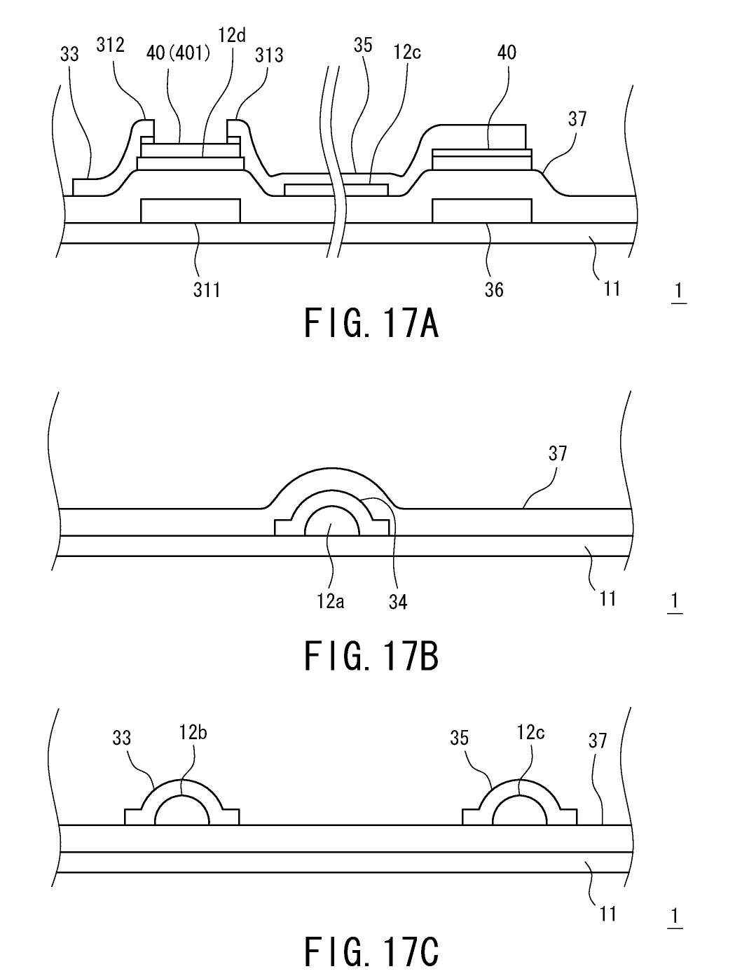

Then, the data line 33, the drain line 35, and the source electrode 312 and the drain electrode 313 of the TFT 31 are simultaneously formed from the same material in the same process as shown in FIGS. 17A and 17C. As shown in FIGS. 17A and 17C, the data line 33 is formed so to be superimposed on the second base 12b, and the drain line 35 is formed so as to be superimposed on the third base 12c. Neither the data line 33 nor the drain line 35 is formed in an area shown in FIG. 17B. To be specific, a conductor film that is a material of the data line 33, the drain line 35, and the source electrode 312 and the drain electrode 313 of the TFT 31 (a second conductor film) is formed on the transparent substrate 11 subjected to the above processes. Then, the formed second conductor film is subjected to patterning into a given shape.

The second conductor film has a single or multi-layer structure, and is preferably made from titanium, aluminum, chromium, or molybdenum. In the display panel substrate 1 according to the preferred embodiment of the present invention, the second conductor film has a two-layer structure, and the two layers are made from different materials. To be specific, the second conductor film has a two-layer structure consisting of a first sub conductor film 411 that is closer to the transparent substrate 11 and a second sub conductor film 412 that is closer to the pixel electrode 32. For the first sub conductor film 411, titanium is preferably used. For the second sub conductor film 412, aluminum is preferably used.

For a method for forming the second conductor film, sputtering is preferably used. For the patterning of the second conductor film, dry etching using a Cl₂ gas and an BCl₃ gas or wet etching using phosphoric acid, acetic acid, or nitric acid may be used. The patterning of the second conductor film forms the data line 33, the drain line 35, and the source electrode 312 and the drain electrode 313 of the TFT 31. In the patterning, the channel region is formed in the second sub semiconductor film 402 by performing etching using the source electrode 312 and the drain electrode 313 as a mask.

Through the above processes, the TFT 31 (the gate electrode 311, the source electrode 312, the drain electrode 313), the data line 33, the scanning line 34, the drain line 35, and the auxiliary capacitance signal line 36 are formed on the transparent substrate 11 as shown in FIGS. 17A to 17C.

As shown in FIG. 17B, the scanning line 34 is formed so as to be superimposed on the first base 12a. As shown in FIG. 17C, the data line 33 is formed so as to be superimposed on the second base 12b, and the drain line 35 is formed so as to be superimposed on the third base 12c. Accordingly, the widths of the scanning line 34, the data line 33, and the drain line 35 can be reduced as compared to the configuration that the bases 12a, 12b, and 12c are not included while maintaining the signal transfer capabilities of the scanning line 34, the data line 33, and the drain line 35. Thus, the aperture ratio can be improved. In other words, the signal transfer capabilities of the scanning line 34, the data line 33, and the drain line 35 can be improved without increasing their widths.

Because the semiconductor film 40 and the drain electrode 313 are formed so as to be superimposed on the fourth base 12d, the drain electrode 313 is curved so as to have an arch shape and is opposed to the source electrode 312 as shown in FIG. 17A. Accordingly, the length of the drain electrode 313 and the length of the channel region can be increased as compared to the configuration that the fourth base 12d is not included. Thus, the channel length of the TFT 31 can be increased without increasing the apparent length of the drain electrode 313 of the TFT 31 or increasing the size of the TFT 31. The increase in the channel length of the TFT 31 makes it possible to supply sufficient current to the pixel electrode 32 in a short period of time, which improves the capability of the TFT 31. As described above, the channel length of the TFT 31 can be increased without lowering the aperture ratio by increasing the size of the TFT 31.

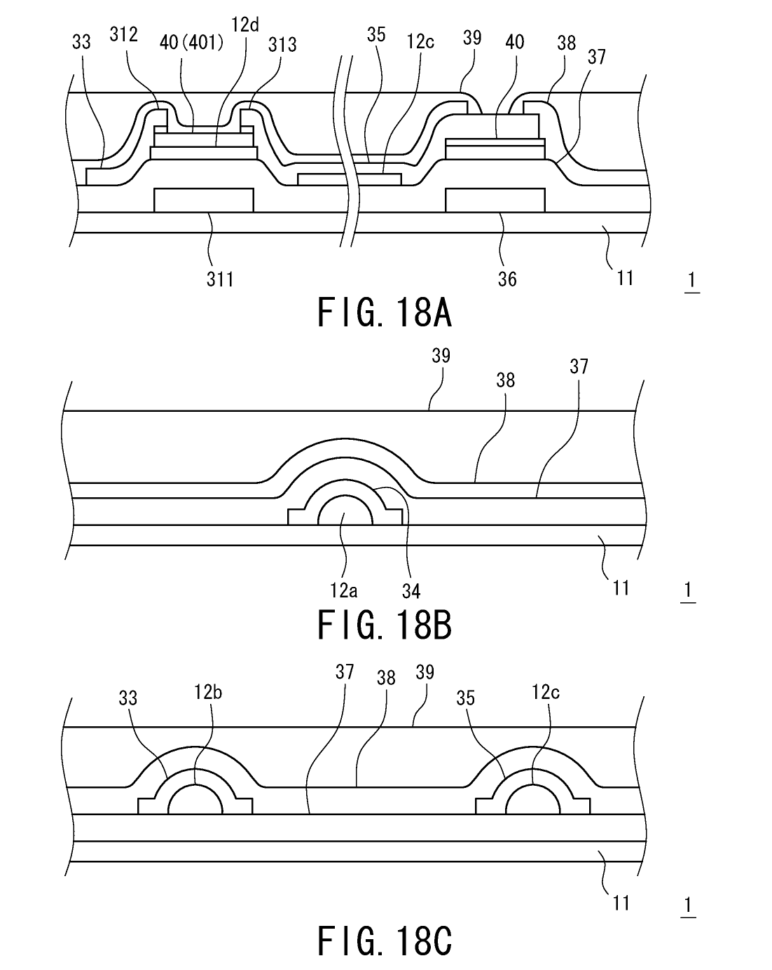

Then, the passivation film (second insulator film) 38 and the organic insulator film (third insulator film) 39 are formed on the transparent substrate 11 subjected to the above processes as shown in FIGS. 18A to 18C. To be specific, the passivation film (second insulator film) 38 is formed on the transparent substrate 11 subjected to the above processes. For the passivation film (second insulator film) 38, an SiNx (silicon nitride) film that has a thickness of about 300 nm is preferably used. For a method for forming the passivation film (second insulator film) 38, CVD is preferably used. Then, the organic insulator film (third insulator film) 39 is formed on the formed passivation film (second insulator film) 38. For the organic insulator film (third insulator film) 39, an acrylic resin material is preferably used.

The formed organic insulator film (third insulator film) 39 is subjected to patterning into a given pattern preferably by photolithography. In the patterning, an opening (contact hole) arranged to make the pixel electrode 32 and the drain line 35 electrically continuous is formed in the organic insulator film (third insulator film) 39.

By the formation of the opening (contact hole) in the organic insulator film (third insulator film) 39, a given portion of the passivation film (second insulator film) 38 is exposed through the opening (contact hole). Then, patterning of the passivation film (second insulator film) 38 is performed by using the organic insulator film (third insulator film) 39 subjected to the patterning as a mask. By the patterning of the passivation film (second insulator film) 38, a portion of the passivation film (second insulator film) 38 that is exposed through the opening (contact hole) of the organic insulator film (third insulator film) 39 is removed. Accordingly, an opening (contact hole) is formed also in the passivation film (second insulator film) 38. For the patterning of the passivation film (second insulator film) 38, dry etching using a CF₄+O₂ gas or a SF₆+O₂ gas is preferably used.

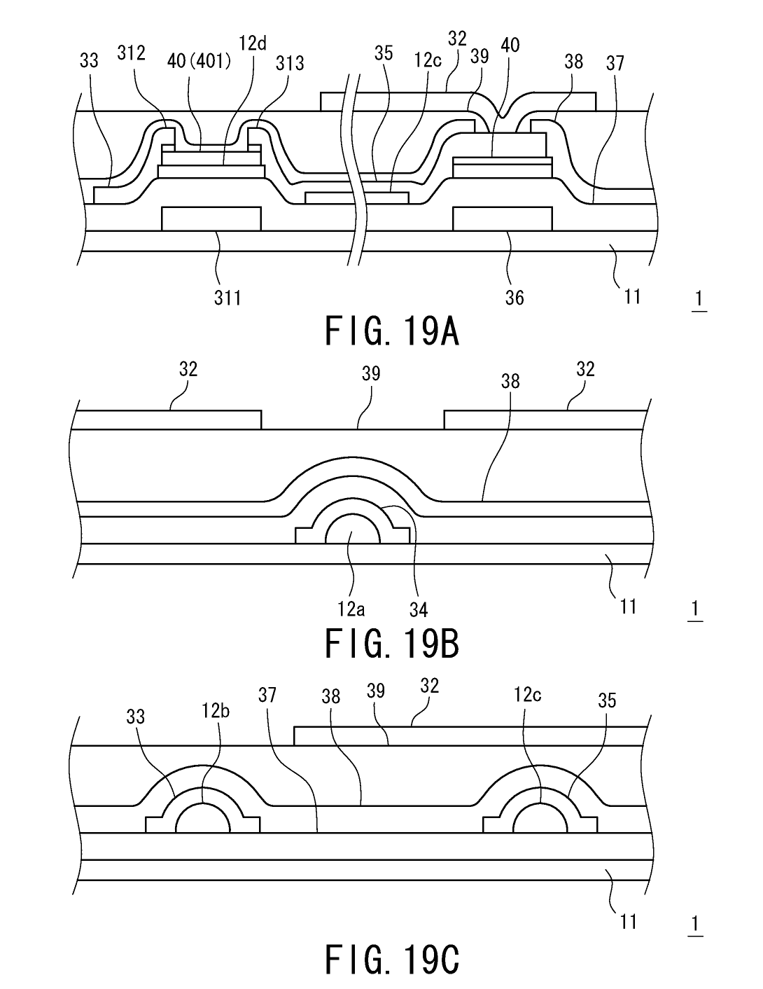

Then, the pixel electrode 32 is formed on the organic insulator film (third insulator film) 39 as shown in FIGS. 19A to 19C. For the pixel electrode 32, an ITO (Indium Tin Oxide) film that has a thickness of about 100 nm is preferably used. For a method for forming the pixel electrode 32, sputtering is preferably used.

Through the above processes, the display panel substrate 1 according to the preferred embodiment of the present invention is manufactured.

Next, a description of a method for manufacturing a display panel 5 that uses the display panel substrate 1 according to the preferred embodiment of the present invention is provided.

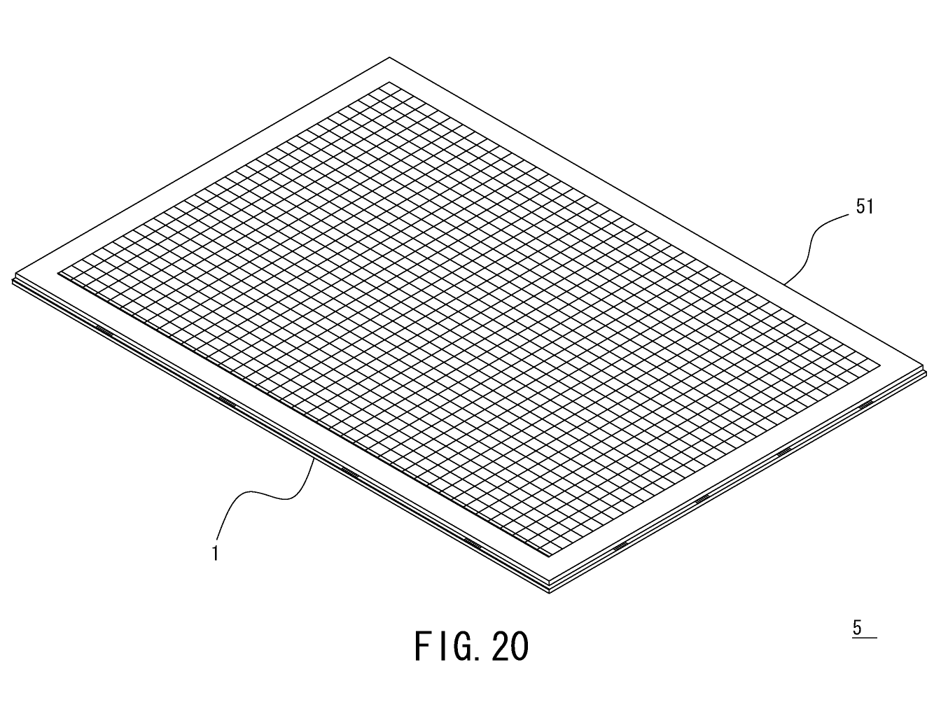

FIG. 20 is an external perspective view schematically showing the structure of the display panel 5 that uses the display panel substrate 1 according to the preferred embodiment of the present invention. As shown in FIG. 20, the display panel 5 according to the preferred embodiment of the present invention includes a TFT array substrate (the display panel substrate 1 according to the preferred embodiment of the present invention) and a common substrate (color filter) 51. Liquid crystals are filled between the substrates. For the structure of the display panel 5, a structure generally used for a liquid crystal display panel may be used, and a detailed description thereof is omitted.

The method for manufacturing the display panel 5 according to the preferred embodiment of the present invention includes a TFT array substrate manufacturing process, a color filter manufacturing process, and a panel (cell) manufacturing process. The TFT array substrate manufacturing process is as described above.

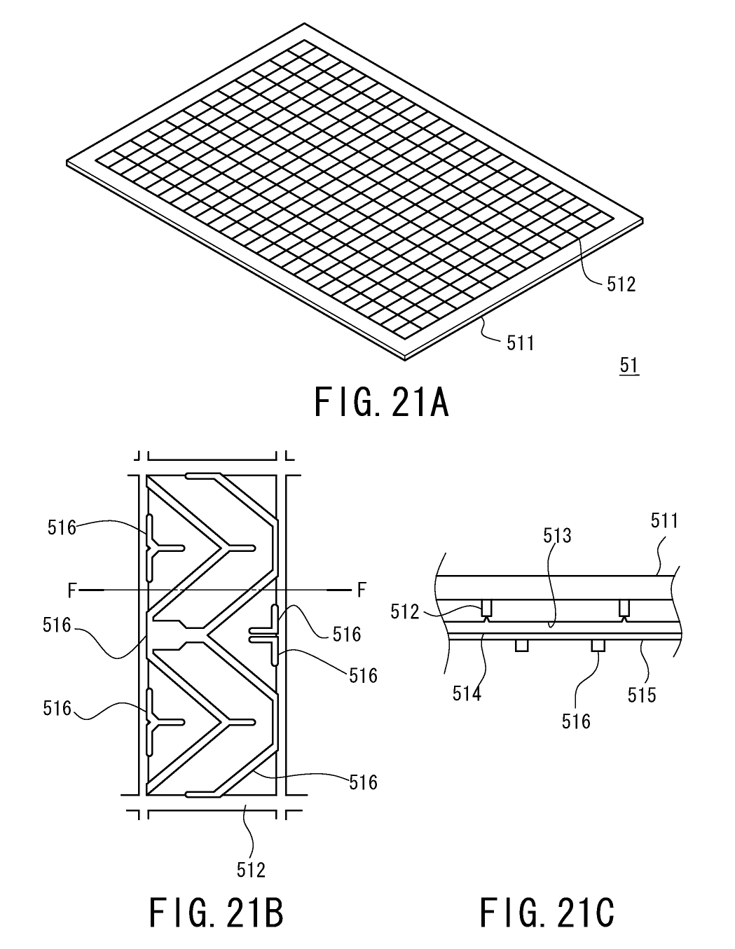

Descriptions of the structure of the common substrate (color filter) 51 and the color filter manufacturing process are provided. FIGS. 21A to 21C are views schematically showing the structure of the common substrate (color filter) 51. To be specific, FIG. 21A is a perspective view schematically showing the overall structure of the common substrate (color filter) 51, FIG. 21B is a plan view showing the structure of one pixel on the common substrate (color filter) 51, and FIG. 21C is a cross-sectional view showing the cross-sectional structure of the pixel along the F-F line in FIG. 21B.

As shown in FIGS. 21A to 21C, the common substrate (color filter) 51 has a configuration that a black matrix 512 is formed on a transparent substrate 511 preferably made from glass, and color layers 513 made from color resists of red, green, and blue colors are formed in the squares of the black matrix 512. The squares in which the color layers 513 are formed are arranged in given order. A protective film 514 is formed on the black matrix 512 and the color layers 513, and a transparent electrode (common electrode) 515 is formed on the protective film 514. Alignment control structural elements 516 arranged to control alignment of the liquid crystals are formed on the transparent electrode (common electrode) 515.

The color filter manufacturing process includes a black matrix forming process, a color layer forming process, a protective film forming process, and a transparent electrode (common electrode) forming process.

Details of the black matrix forming process by a resin BM method are provided below. First, a BM resist (a photosensitive resin composition containing a black color agent) is applied on the transparent substrate 511. Then, the applied BM resist is subjected to patterning into a given pattern preferably by photolithography. Thus, the black matrix 512 that has the given pattern is obtained.

In the color layer forming process, the color layers 513 of the red, green, and blue colors for color display are formed. Details of the color layer forming process by a color resist method are provided below. First, a color resist (a solution of a photosensitive material in which a pigment of a given color is dispersed) is applied on the transparent substrate 511 on which the black matrix 512 is formed. Then, the applied color resist is subjected to patterning into a given pattern preferably by photolithography. This process is performed for each of the red, green, and blue colors. Thus, the color layers 513 of the given colors are obtained.

The method used in the black matrix forming process is not limited to the resin BM method, and a known method such as a chromium BM method and an overlap method may be used. The method used in the color layer forming process is neither limited to the color resist method, and a known method such as a printing method, a dyeing method, an electrodeposition method, a transfer method, and a photo-etching method may be used. In addition, a back-face exposure method by which the color layers 513 are formed first and the black matrix 512 is formed second may be used.

In the protective film forming process, the protective film 514 is formed on the black matrix 512 and the color layers 513. For a method for forming the protective film 514, a method for applying a protective film material on the transparent substrate 511 subjected to the above processes with the use of a spin coater (an overcoating method), or a method for forming the protective film 514 that has a given pattern by printing or photolithography (a patterning method) may be used. For the protective film material, an acrylic resin or an epoxy resin is preferably used.

In the transparent electrode (common electrode) forming process, the transparent electrode (common electrode) 515 is formed on the protective film 514. With a masking method, the transparent electrode (common electrode) 515 is formed by putting a mask on the transparent substrate 511 subjected to the above processes and depositing ITO (Indium Tin Oxide) thereon preferably by sputtering.

Then, the alignment control structural elements 516 are formed preferably by photolithography. To be specific, a photosensitive material is applied on the transparent substrate 511 subjected to the above processes and is exposed to have a given pattern with the use of a photomask. Then, unnecessary portions are removed in the subsequent developing process, so that the alignment control structural elements 516 that have a given pattern are obtained.

Through these processes, the common substrate (color filter) 51 is obtained.

Next, a description of the panel (cell) manufacturing process is provided. First, alignment films are each formed on the TFT array substrate obtained by the above processes (the display panel substrate 1 according to the preferred embodiment of the present invention) and the common substrate (color filter) 51. Then, the formed alignment films are subjected to alignment process. Then, the display panel substrate 1 according to the preferred embodiment of the present invention and the common substrate (color filter) 51 are bonded to each other, and liquid crystals are filled therebetween.

A method for forming the alignment films on the display panel substrate 1 according to the preferred embodiment of the present invention and the common substrate (color filter) 51 is described below. First, alignment materials are each applied on the display panel substrate 1 according to the preferred embodiment of the present invention and the common substrate (color filter) 51 with the use of an alignment material application device. The alignment materials are solutions containing materials of the alignment films. For the alignment material application device, a conventionally used device such as a cylinder printing press and an inkjet printing press may be used. The applied alignment materials are heated and baked by an alignment film sintering device.

Then, the baked alignment films are subjected to alignment process. For the alignment process, a known processing method such as a method for making small scratches on the alignment films with the use of a rubbing roll and a photo-alignment processing of adjusting surface properties of the alignment films by irradiating the alignment films with light energy such as ultraviolet light may be used. It should be noted that the baked alignment films may not be subjected to the alignment process.

Then, a sealing material is applied on the display panel substrate 1 according to the preferred embodiment of the present invention or the common substrate (color filter) 51 with the use of a seal patterning device.

Then, spacers arranged to keep a cell gap uniformly at a given value are dispersed on the display panel substrate 1 according to the preferred embodiment of the present invention or the common substrate (color filter) 51 with the use of a spacer dispersing device. Then, liquid crystals are drop-filled in regions surrounded by the sealing material on the display panel substrate 1 according to the preferred embodiment of the present invention or the common substrate (color filter) 51 with the use of a liquid crystal drop fill device.

The display panel substrate 1 according to the preferred embodiment of the present invention and the common substrate (color filter) 51 are bonded to each other under a reduced pressure atmosphere. Liquid crystals may be injected between the display panel substrate 1 according to the preferred embodiment of the present invention and the common substrate (color filter) 51 after the curing of the sealing material.

Through the above processes, the display panel 5 according to the present invention is obtained.

The foregoing descriptions of the preferred embodiments of the present invention have been presented for purposes of illustration and description with reference to the drawings. However, it is not intended to limit the present invention to the preferred embodiments, and modifications and variations are possible as long as they do not deviate from the principles of the present invention.

1-15. (canceled)

16. A display panel substrate comprising:
a base that has a substantially semicircular cross-section; and
a trace that has a thin film shape, and at least a portion of which is superimposed on the base.

17. The display panel substrate according to claim 16, further comprising:
a pixel electrode; and
a thin film transistor arranged to drive the pixel electrode,
wherein the trace comprises at least one of a data line arranged to transfer an image signal to the thin film transistor, a scanning line arranged to transfer a selection pulse to a gate electrode of the thin film transistor, and a drain line arranged to electrically connect a drain electrode of the thin film transistor and the pixel electrode.

18. The display panel substrate according to claim 16, wherein the base is made from a photosensitive resin material.

19. A display panel comprising:
the display panel substrate according to claim 16; and
a common substrate.

20. A display panel substrate comprising:
a base that has a substantially semicircular cross-section in a direction perpendicular to a longitudinal direction of the base; and
a trace that has a thin film shape and has a longitudinal direction substantially parallel to the longitudinal direction of the base, at least a portion of the trace being superimposed on the base, at least a portion of the trace having a substantially arc cross-section in a direction perpendicular to the longitudinal direction of the trace.

21. The display panel substrate according to claim 20, further comprising:
a pixel electrode; and
a thin film transistor arranged to drive the pixel electrode,
wherein the trace comprises at least one of a data line arranged to transfer an image signal to the thin film transistor, a scanning line arranged to transfer a selection pulse to a gate electrode of the thin film transistor, and a drain line arranged to electrically connect a drain electrode of the thin film transistor and the pixel electrode.

22. The display panel substrate according to claim 20, wherein the base is made from a photosensitive resin material.

23. A display panel comprising:
the display panel substrate according to claim 20; and
a common substrate.

24. A display panel substrate comprising:
a pixel electrode;
a thin film transistor that is arranged to drive the pixel electrode and includes a drain electrode and a channel region; and
a base that has a substantially semicircular cross-section,
wherein at least portions of the drain electrode and the channel region are superimposed on the base.

25. The display panel substrate according to claim 24, wherein the base is made from a photosensitive resin material.

26. A display panel comprising:
the display panel substrate according to claim 24; and
a common substrate.

27. A method for manufacturing a display panel substrate comprising the steps of:
forming a base that has a substantially square cross-section;
making the base take a substantially semicircular cross-section; and
forming a trace at least a portion of which is superimposed on the base.

28. A method for manufacturing a display panel substrate comprising the steps of:
forming a base that has a thin film shape and has a substantially square cross-section in a direction perpendicular to a longitudinal direction of the base;
making the base take a substantially semicircular cross-section in the direction perpendicular to the longitudinal direction of the base; and
forming a trace that has an area that has a longitudinal direction substantially parallel to the longitudinal direction of the base, at least a portion of the area being superimposed on the base, at least a portion of the area having a substantially arc cross-section in a direction perpendicular to the longitudinal direction of the trace.

29. A method for manufacturing a display panel substrate comprising the steps of:
forming a base that has a thin film shape on a transparent substrate;
making the base take a substantially semicircular cross-section in a direction perpendicular to a longitudinal direction of the base; and
forming a scan line that has an area that has a longitudinal direction substantially parallel to the longitudinal direction of the base, a portion of the area being superimposed on the base.

30. A method for manufacturing a display panel substrate comprising the steps of:
forming a base that has a thin film shape on a transparent substrate subjected to a given process;
making the base take a substantially semicircular cross-section in a direction perpendicular to a longitudinal direction of the base; and
forming a data line that has an area that has a longitudinal direction substantially parallel to the longitudinal direction of the base, at least a portion of the area being superimposed on the base.

31. A method for manufacturing a display panel substrate comprising the steps of:
forming a base that has a thin film shape on a transparent substrate subjected to a given process;
making the base take a substantially semicircular cross-section in a direction perpendicular to the longitudinal direction of the base; and
forming a drain line that has an area that has a longitudinal direction substantially parallel to the longitudinal direction of the base, at least a portion of the area being superimposed on the base.

32. A method for manufacturing a display panel substrate on which a thin film transistor including a gate electrode, a source electrode, and a drain electrode is formed, the method comprising the steps of:
forming a base that has a thin film shape and is superimposed on the gate electrode;
making the base take a substantially semicircular cross-section in a direction perpendicular to a longitudinal direction of the base; and
forming the drain electrode at least a portion of which is superimposed on the base.

33. The method for manufacturing the display panel substrate according to claim 27, wherein the base is made from a photosensitive resin material.

34. The method for manufacturing the display panel substrate according to claim 33, wherein the step of making the base take the substantially semicircular cross-section in the direction perpendicular to the longitudinal direction of the base comprises the step of subjecting the base to heating or curing.

35. A method for manufacturing a display panel comprising the method for manufacturing the display panel substrate according to claim 27.

36. The method for manufacturing the display panel substrate according to claim 28, wherein the base is made from a photosensitive resin material.

37. The method for manufacturing the display panel substrate according to claim 36, wherein the step of making the base take the substantially semicircular cross-section in the direction perpendicular to the longitudinal direction of the base comprises the step of subjecting the base to heating or curing.

38. A method for manufacturing a display panel comprising the method for manufacturing the display panel substrate according to claim 28.

39. The method for manufacturing the display panel substrate according to claim 29, wherein the base is made from a photosensitive resin material.

40. The method for manufacturing the display panel substrate according to claim 39, wherein the step of making the base take the substantially semicircular cross-section in the direction perpendicular to the longitudinal direction of the base comprises the step of subjecting the base to heating or curing.

41. A method for manufacturing a display panel comprising the method for manufacturing the display panel substrate according to claim 29.

42. The method for manufacturing the display panel substrate according to claim 30, wherein the base is made from a photosensitive resin material.

43. The method for manufacturing the display panel substrate according to claim 42, wherein the step of making the base take the substantially semicircular cross-section in the direction perpendicular to the longitudinal direction of the base comprises the step of subjecting the base to heating or curing.

44. A method for manufacturing a display panel comprising the method for manufacturing the display panel substrate according to claim 30.

45. The method for manufacturing the display panel substrate according to claim 31, wherein the base is made from a photosensitive resin material.

46. The method for manufacturing the display panel substrate according to claim 45, wherein the step of making the base take the substantially semicircular cross-section in the direction perpendicular to the longitudinal direction of the base comprises the step of subjecting the base to heating or curing.

47. A method for manufacturing a display panel comprising the method for manufacturing the display panel substrate according to claim 31.

48. The method for manufacturing the display panel substrate according to claim 32, wherein the base is made from a photosensitive resin material.

49. The method for manufacturing the display panel substrate according to claim 48, wherein the step of making the base take the substantially semicircular cross-section in the direction perpendicular to the longitudinal direction of the base comprises the step of subjecting the base to heating or curing.

50. A method for manufacturing a display panel comprising the method for manufacturing the display panel substrate according to claim 32.
